(19) United States
(12) Patent Application Publication
(10) Pub. No.: US 2014/0312224 A1
(43) Pub. Date: Oct. 23, 2014

(54) PATTERN INSPECTION METHOD AND PATTERN INSPECTION APPARATUS

(71) Applicants: ADVANTEST CORPORATION, Tokyo (JP); TOPPAN PRINTING CO. LTD., Tokyo (JP)

(72) Inventors: Tsutomu Murakawa, Tokyo (JP); Isao Yonekura, Tokyo (JP); Shinya Morisaki, Shimotsuke (JP)

(73) Assignees: ADVANTEST CORPORATION, Tokyo (JP); TOPPAN PRINTING CO. LTD., Tokyo (JP)

(21) Appl. No.: 14/254,567

(22) Filed: Apr. 16, 2014

(30) Foreign Application Priority Data
Apr. 17, 2013 (JP) 2013-086421

(51) Int. Cl. H01J 37/28; H01J 37/29

(52) U.S. Cl. CPC H01J 37/28; H01J 37/292
USPC 250/307; 250/310

(57) ABSTRACT

A first differential image of a defect observation region including an observation target pattern is generated by a differential value between signals from electron detectors arranged in a direction of edges of the observation target pattern. A three-dimensional shape of a defect is obtained by subjecting the first differential image to integral process. Subsequently, a second differential image of a reference observation region, including a reference pattern having the same shape as the observation target pattern is generated by a differential value between signals from electron detectors arranged in a direction orthogonal to edges of the reference pattern. A three-dimensional shape of the reference pattern is obtained by subjecting the second differential image to the integral process. Then, a three-dimensional shape of the observation target pattern including the defect is obtained by combining the three-dimensional shapes of the defect and the reference pattern together.

### CROSS-REFERENCE TO RELATED APPLICATIONS

This application is based upon and claims and the benefit of priority of the prior Japanese Patent Application No. 2013-086421, filed Apr. 17, 2013, the entire contents of which are incorporated herein by reference.

### FIELD

The embodiments discussed herein are related to a pattern inspection method and a pattern inspection apparatus, which are configured to find a three-dimensional shape of a pattern from a secondary electron image obtained by scanning of an electron beam.

### BACKGROUND

With the progress of higher densities and finer microfabrication in recent years of semiconductor devices and photomasks for manufacturing semiconductor devices, shapes of patterns to be formed on substrates, as well as minute changes in the shapes of the patterns such as depths, heights and inclination angles of sidewalls, are more likely to have large influence on end products. For this reason, there has been a demand for a defect inspection technique for measuring the dimensions and shape of a pattern with a high degree of accuracy.

A defect inspection of a wafer or a photomask is first conducted by using a high-throughput optical inspection apparatus. Such an optical inspection apparatus detect a defect as small as 10 nm or below, for example. Nevertheless, the optical inspection apparatus may not be capable to distinguish the shape of the defect due to the restriction of resolution.

Accordingly, when a defect is detected by the optical inspection apparatus, the position, shape, and size of the defect are checked in a subsequent inspection step (a defect review step). A scanning electron microscope (SEM) is generally used in the defect review step. The scanning electron microscope measures the shape of the small defect, which may not be fully captured with the optical inspection apparatus.

One of methods of observing a defect by using the scanning electron microscope is a method using a plurality of electron detectors disposed around a primary electron beam. In this method, a three-dimensional shape of a surface of a sample including a defective portion may be obtained by finding differences among images (SEM images) acquired by respective electron detectors.

Patent Document 1: Japanese Laid-open Patent Publication No. 03-193645

Patent Document 2: Japanese Laid-open Patent Publication No. 2012-112927

Patent Document 3: Japanese Laid-open Patent Publication No. 2007-225531

Patent Document 4: Japanese Laid-open Patent Publication No. 2007-129059

### SUMMARY

### Problems to be Solved by the Invention

If the pattern has a defect or the like, luminance unevenness extending in the same direction as a scanning direction of an electron beam may occur in a SEM image when a pattern is observed with the scanning electron microscope. In this case, when the three-dimensional image of the surface of the sample is reproduced by finding the differences among the images acquired with the plurality of electron detectors, irregularities which do not exist may appear due to an influence of the uneven luminance. As a result, it is not possible to acquire accurate irregularity information by the observation using the scanning electron microscope.

In view of the above, it is an object of the present invention to provide a pattern inspection method and a pattern inspection apparatus, which are capable of generating a three-dimensional image including accurate irregularity information even if luminance unevenness occurs in a SEM image due to a defect or the like.

### Means for Solving the Problem

According to a first aspect of the present invention, there is provided a pattern inspection method using a scanning electron microscope provided with a plurality of electron detectors disposed around an optical axis of a primary electron beam. The method includes the steps of: setting a defect observation region including an observation target pattern having a defect; acquiring scanning electron microscopic images respectively with the plurality of electron detectors by scanning the defect observation region with the primary electron beam; acquiring a first differential image by finding a difference between the scanning electron microscopic images acquired with the electron detectors disposed in the same direction as an extending direction of an edge of the observation target pattern; setting a reference observation region including a reference pattern having the same shape as the observation target pattern; acquiring scanning electron microscopic images respectively with the plurality of electron detectors by scanning the reference observation region with the primary electron beam; acquiring a second differential image by finding a difference between the scanning electron microscopic images acquired with the electron detectors disposed in a direction orthogonal to an extending direction of an edge of the reference pattern; and reproducing a three-dimensional shape of the observation target pattern based on the first differential image and the second differential image.

According to another aspect of the present invention, there is provided a pattern inspection apparatus including: an observation region setting unit configured to set a defect observation region on a surface of a sample at a portion where an observation target pattern having a defect is present, and to set a reference observation region on the surface of the sample at a portion having a reference pattern of the same shape as the observation target pattern and having no defect; an electron scanning unit configured to scan the defect observation region and the reference observation region with a primary electron beam; a plurality of electron detector disposed around an optical axis of the primary electron beam and each configured to detect electrons emitted from the surface of the sample by irradiation of the primary electron beam; a signal processing unit configured to generate a plurality of scanning electron microscopic images respectively based on detection signals from the plurality of electron detectors; and an analysis unit configured to calculate a three-dimensional shape of the observation target pattern based on the plurality of scanning electron microscopic images. In the pattern inspection apparatus, the analysis unit reproduces the three-dimensional shape of the observation target pattern by executing the steps of: generating a three-dimensional shape of the defect based on a first differential image of the defect observation region acquired by finding a difference between the scanning electron microscopic images acquired with the electron detectors disposed in the same direction as an extending direction of an edge of the observation target pattern; generating a three-dimensional shape of the reference pattern based on a second differential image of the reference observation region acquired by finding a difference between the scanning electron microscopic images acquired with the electron detectors disposed in a direction orthogonal to an extending direction of the edge of the reference pattern; and combining the three-dimensional shape of the defect and the three-dimensional shape of the reference pattern together.

### Effect of the Invention

According to the above-described aspects, a three-dimensional shape of an observation target pattern including a defect is obtained by: separately acquiring a three-dimensional shape of a defective portion and a three-dimensional shape of a pattern portion; and combining the three-dimensional shapes together. Thus, even if luminance unevenness occurs due to the defective portion, it is still possible to obtain a three-dimensional shape without any recesses or projections attributed to the luminance unevenness.

### BRIEF DESCRIPTION OF DRAWINGS

FIG. 1 is a block diagram of a pattern inspection apparatus according to an embodiment of the present invention;

FIG. 2 is a perspective view showing a layout of electron detectors in the pattern inspection apparatus of FIG. 1;

FIG. 3 is a plan view showing an example of an observation region;

FIG. 4 is a scanning electron microscopic image showing a result of observation of the observation region of FIG. 3 with the pattern inspection apparatus of FIG. 1;

FIG. 5 is a differential image of the observation region of FIG. 4;

FIG. 6 is a view showing a result of reproduction of a three-dimensional shape of the observation region by subjecting the differential image of FIG. 5 to integral process;

FIG. 7 is a flowchart showing a pattern inspection method according to the embodiment;

FIG. 8 is a plan view showing a layout of a defect observation region and the electron detectors;

FIG. 9 is a view showing a pattern which emerges in a differential image (a first differential image) of the defect observation region of FIG. 8;

FIG. 10 is a plan view showing a layout of a reference observation region and the electron detectors;

FIG. 11 is a view showing a pattern which emerges in a differential image (a second differential image) of the reference observation region of FIG. 10;

FIG. 12 is a perspective view showing a three-dimensional shape obtained by performing integral process on the first differential image of FIG. 9;

FIG. 13 is a perspective view showing a three-dimensional shape obtained by performing the integral process on the second differential image of FIG. 11;

FIG. 14 is a perspective view showing a three-dimensional shape obtained by combining three-dimensional shape data of FIG. 12 and three-dimensional shape data of FIG. 13 together;

FIG. 15 is an electron microscopic image of a defect observation region of an example;

FIG. 16 is an electron microscopic image of a reference observation region of the example;

FIG. 17 is a differential image of the defect observation region of the example;

FIG. 18 is a differential image of the reference observation region of the example;

FIG. 19 is a view showing a three-dimensional shape obtained by performing the integral process on the differential image of FIG. 17;

FIG. 20 is a view showing a three-dimensional shape obtained by performing the integral process on the differential image of FIG. 18;

FIG. 21 is a view showing a three-dimensional shape obtained by combining three-dimensional shape data of FIG. 19 and three-dimensional shape data of FIG. 20 together; and,

FIG. 22 is a view showing a result of observation of the defect observation region of FIG. 15 by using atomic force microscopy (AFM).

### DESCRIPTION OF EMBODIMENT

An embodiment of the present invention will be described below with reference to the accompanying drawings.

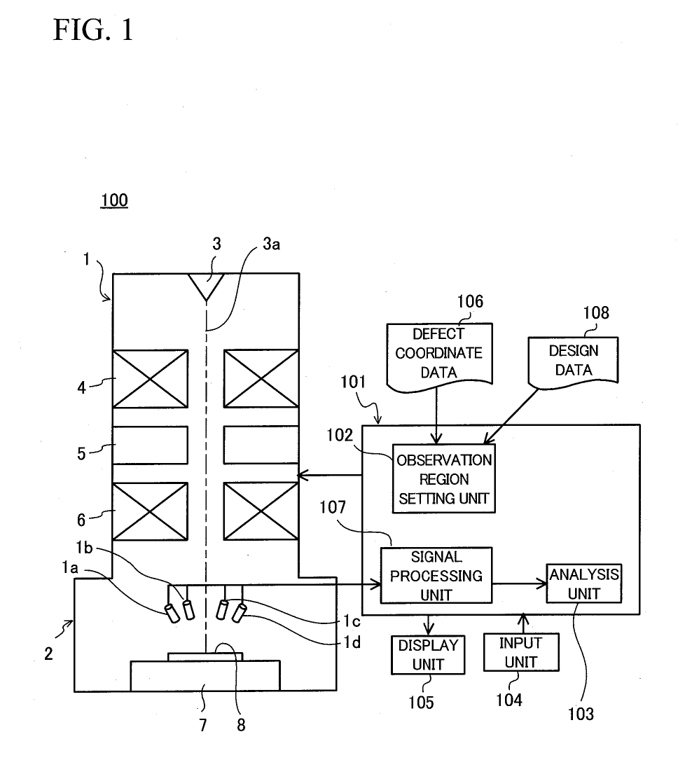

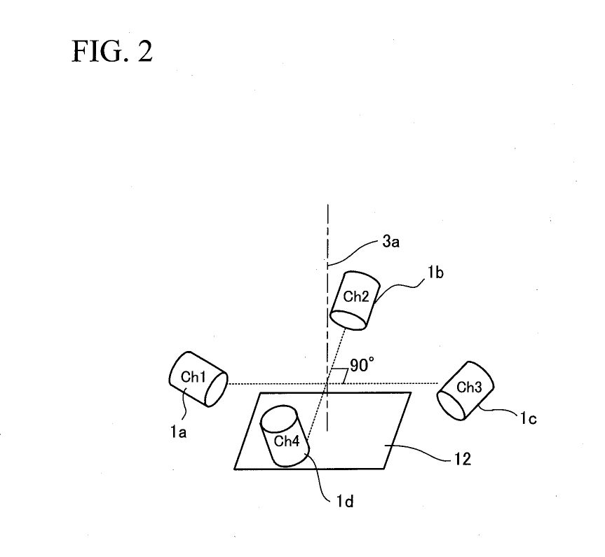

FIG. 1 is a block diagram of a pattern inspection apparatus according to an embodiment of the present invention, and FIG. 2 is a perspective view showing a layout of electron detectors in the pattern inspection apparatus of FIG. 1.

As shown in FIG. 1, a pattern inspection apparatus 100 includes a chamber 2 which encloses a sample 8, an electron scanning unit 1 configured to irradiate the sample 8 with an electron beam 3a; and a control unit 101 configured to control instruments in the electron scanning unit 1 and the chamber 2 and to process measurement data.

The electron scanning unit 1 includes an electron gun 3, and the electron beam 3a is emitted from the electron gun 3. The electron beam 3a is converged by condenser lens 4, positioned with a deflection coil 5, focused with an objective lens 6, and then projected onto a surface of the sample 8.

Moreover, the electron scanning unit 1 includes four electron detectors 1a to 1d.

As shown in FIG. 2, the electron detectors 1a to 1d are located above an observation region 12 of the sample 8. The electron detectors 1a to 1d are disposed around an optical axis of the electron beam 3a at angles of about 90° and symmetrically with one another about the optical axis. Although the layout is not particularly limited, each of the electron detectors 1a to 1d therein is assumed to be disposed in the direction orthogonal to the corresponding side of the rectangular observation region 12.

The electron detectors 1a to 1d are each made from a scintillator or the like, for example, and are configured to detect secondary electrons or reflected electrons generated as a result of the irradiation of the electron beam 3a, and to output amounts of electrons at the positions of the electron detectors 1a to 1d as signals Ch1 to Ch4, respectively.

Meanwhile, as shown in FIG. 1, a stage 7 to support the sample 8 is provided inside the chamber 2. The stage 7 includes a not-illustrated driving mechanism, and is thus capable of moving the sample 8.

The control unit 101 includes an observation region setting unit 102 to set the observation region 12, which is a region on the surface of the sample 8 to be scanned with the electron beam. The observation region setting unit 102 sets a defect observation region on the sample 8 based on defect coordinate data 106 which indicates position coordinates of a defect. The defect coordinate data 106 is obtained as a result of an inspection by an optical inspection apparatus or the like, for example.

In the meantime, the observation region setting unit 102 refers to design data 108 and the defect coordinate data 106, and sets a reference observation region at a portion which is determined to have a pattern (a reference pattern) of the same shape as a pattern in the defect observation region, and yet to contain no defects therein.

Note that the pattern inspection apparatus 100 may also accept the setting of the observation regions by means of a manual operation or by use of an external device. Accordingly, the control unit 101 is provided with an input unit 104 used for the setting of the observation regions by the manual operation or the external device.

Meanwhile, the detection signals Ch1 to Ch4 from the electron detectors 1a to 1d are inputted to a signal processing unit 107. The signal processing unit 107 associates intensities of the detection signals from the electron detectors 1a to 1d with an irradiation position of the electron beam 3a, and thus generates SEM images respectively corresponding to the electron detectors 1a to 1d. The SEM images generated by the signal processing unit 107 are sent to an analysis unit 103 and are displayed on a display unit 105.

An example of an inspection of a pattern using the pattern inspection apparatus 100 will be described below.

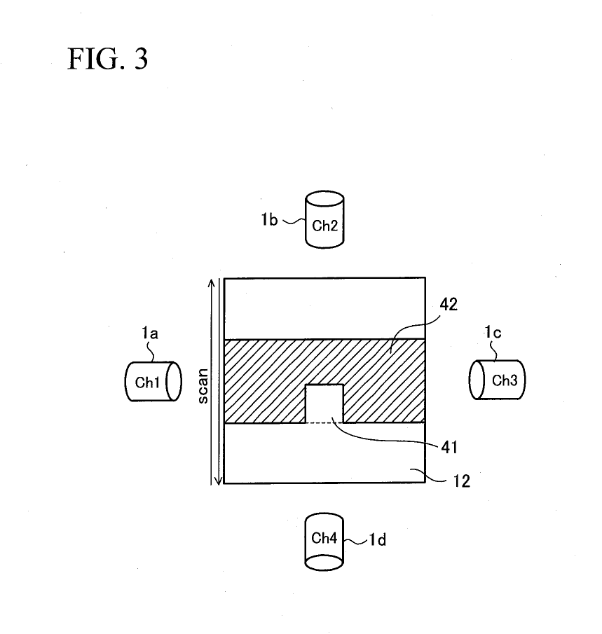

FIG. 3 shows an example in which the defect observation pattern 12 is set in a line pattern 42 as an observation target pattern.

The line pattern 42 is formed by patterning a chromium film which is deposited on a glass substrate. As illustrated in FIG. 3, the line pattern 42 extends in a lateral direction in the defect observation region 12. The line pattern 42 includes a scratch defect 41 which a part of the line pattern 42 is scratched off.

The electron detectors 1a and 1c are arranged in a direction parallel to the line pattern 42 while the electron detectors 1b and 1d are arranged in a direction perpendicular to the line pattern 42.

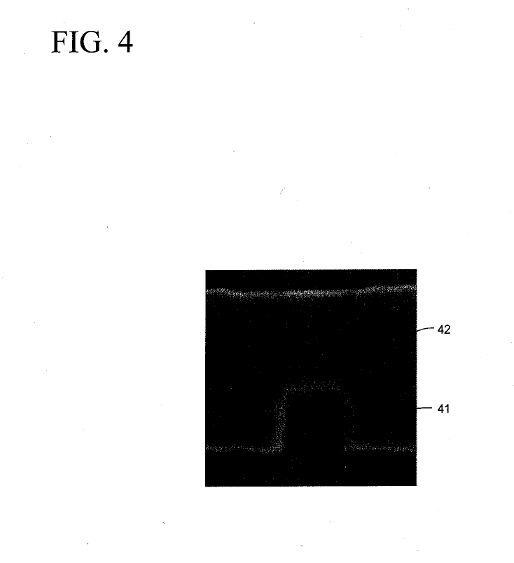

FIG. 4 is a SEM image of the above-described defect observation region 12.

Here, the electron beam 3a is caused to scan in the direction orthogonal to edges of the pattern 42 (the longitudinal direction in FIG. 4) in order to capture the edges of the pattern 42 with high sensitivity and thus to measure an accurate three-dimensional shape. Hence, the SEM image of FIG. 4 is obtained by adding all the signals Ch1 to Ch4 from the electron detectors 1a to 1d and thus forming the signals into an image.

Components corresponding to the locations of the electron detectors 1a to 1d are offset in this SEM image. Thus, the SEM image is formed into an image equivalent to a SEM image obtained by a typical scanning electron microscope provided with a single electron detector.

If there are edges extending in parallel with the scanning direction of the electron beam 3a, as found in the defect 41, a change in the charged state of the surface of the sample at each edge portion becomes larger than those at the other portions, whereby a rate of emission of secondary electrons in the scanning direction of the electron beam 3a changes at the edge of the defect 41. As a consequence, belt-like luminance unevenness occurs around the defect 41.

Next, in order to obtain the three-dimensional shape of the pattern 42, a differential image is obtained by finding a difference between the signals Ch2 and Ch4 of the electron detectors 1b and 1d which are arranged in the direction orthogonal to the edges of the pattern 42.

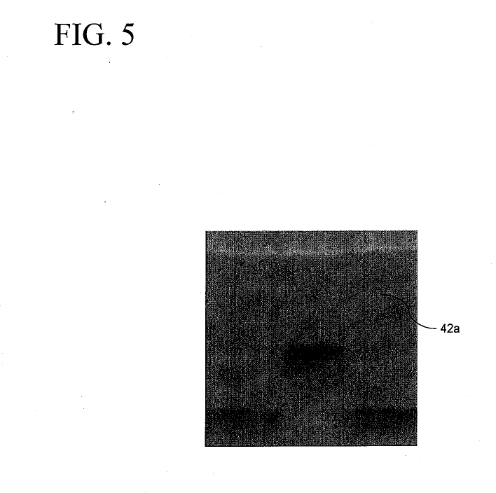

FIG. 5 shows the differential image obtained by finding the difference between the signals Ch2 and Ch4 of the electron detectors 1b and 1d arranged in the direction in parallel with the scanning direction of the electron beam. Here, a pattern 42a on the differential image of FIG. 5 corresponds to the pattern 42 on the SEM image.

The detection signals of the electron detectors 1b and 1d vary depending on the orientation of the edges of the line pattern 42. Accordingly, in the differential image obtained by finding the difference between the signals from the electron detectors 1b and 1d, luminance of the edges of the line pattern 42 corresponds to the inclination of the edges.

By extracting a differential profile representing luminance distribution in the direction used for finding the difference from the differential image, and subjecting to an integral process in the direction used for finding the difference, the three-dimensional shape of the observation region including the pattern 42 is obtained.

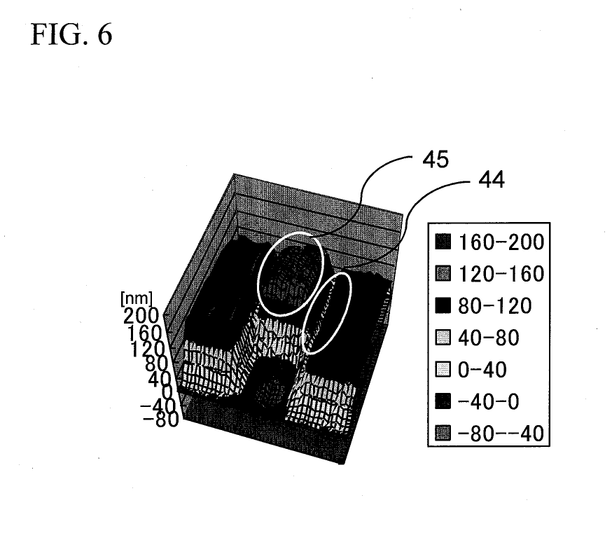

FIG. 6 is a graph showing a result of obtaining the three-dimensional shape of the defect observation region by subjecting the differential image of FIG. 5 to the integral process.

As shown in FIG. 6, a recess 44 and a projection 45, which do not exist in the pattern 42, appear in the three-dimensional shape obtained by subjecting the differential image to the integral process. Thus, the integral process fails to reproduce the accurate three-dimensional shape.

As described above, the luminance unevenness occurs in the vicinity of the defect 41 in the SEM image due to an anomaly of the electric charge near the defect 41. As a result, a luminance value in the vicinity of the defect 41 of the differential image does not accurately reflect the inclination of the edge of the pattern 42, and the accurate three-dimensional shape cannot be obtained in spite of the execution of the integral process.

In view of the above, in the embodiment, a three-dimensional shape of the observation target pattern is obtained in accordance with a method described below.

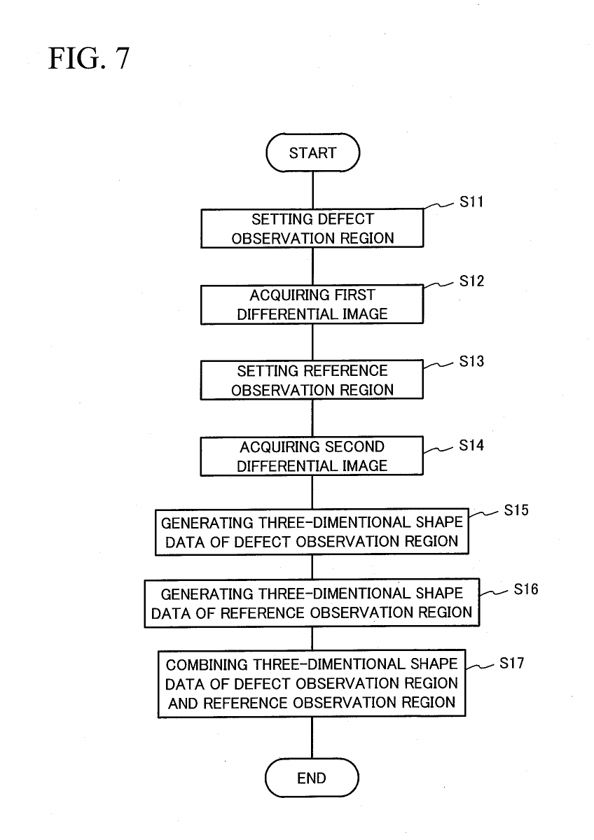

FIG. 7 is a flowchart showing a pattern inspection method according to the embodiment.

First, in step S11, the observation region setting unit 102 of the control unit 101 sets the defect observation region on the basis of the defect coordinate data 106.

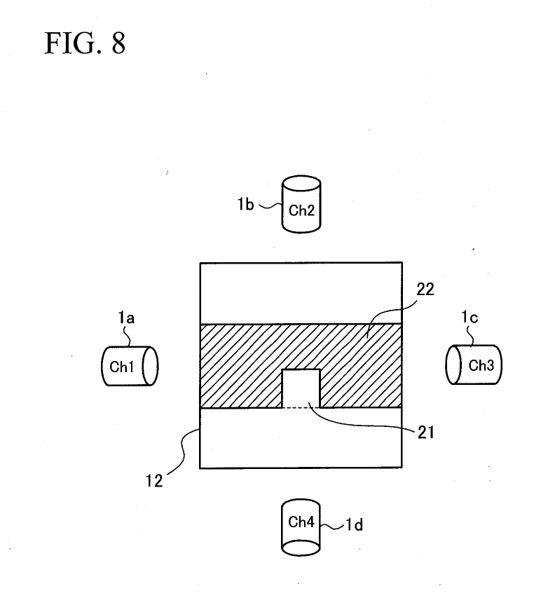

FIG. 8 is a plan view showing a layout of the defect observation region and the electron detectors. In the example of FIG. 8, a rectangular defect observation region 12 is set for a line-shaped observation target pattern 22 including a defect 21. Although not particularly limited, the observation region setting unit 102 herein sets the defect observation region 12 in such a way that the electron detectors 1a to 1d are positioned in the parallel direction and the perpendicular direction to the observation target pattern 22.

Next, in step S12 of FIG. 7, the electron scanning unit 1 (see FIG. 1) scans the defect observation region 12 by irradiating the defect observation region 12 with the electron beam. It is preferable that the electron beam scan in the direction orthogonal to edges of the observation target pattern 22 in order to accurately capture the edges of the observation target pattern 22.

Moreover, in the embodiment, the signal processing unit 107 of the control unit 10 generates a first differential image by finding a difference between the detection signals Ch1 and Ch3 from the electron detectors 1a and 1c which are arranged in the direction parallel to the observation target pattern 22.

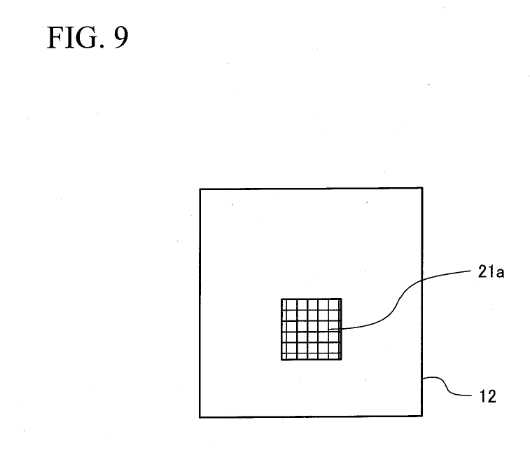

FIG. 9 is a view showing a differential image (the first differential image) of the observation region of FIG. 8.

Each of the edges of the observation target pattern 22 is detected substantially with the same luminance by the electron detectors 1a and 1c which are arranged in the direction parallel to the edges. Accordingly, as shown in FIG. 9, the edges of the observation target pattern 22 are eliminated from the first differential image. Also, the luminance unevenness attributed to the defect 21 is eliminated as well.

On the other hand, among the edges of the defect 21, the edges of the defect 21 extending in the direction orthogonal to the edges of the observation target pattern 22 are detected with different luminance by the electron detectors 1a and 1c. For this reason, the edges of the defect 21a are highlighted in the first differential image. As a consequence, only the defect 21a is left in the first differential image.

Next, in step S13 of FIG. 7, the observation region setting unit 102 refers to the design data and the defect coordinate data, and sets a reference observation region at a portion which is determined to have a pattern (a reference pattern) of the same shape as the pattern in the defect observation region, and yet contain no defects therein.

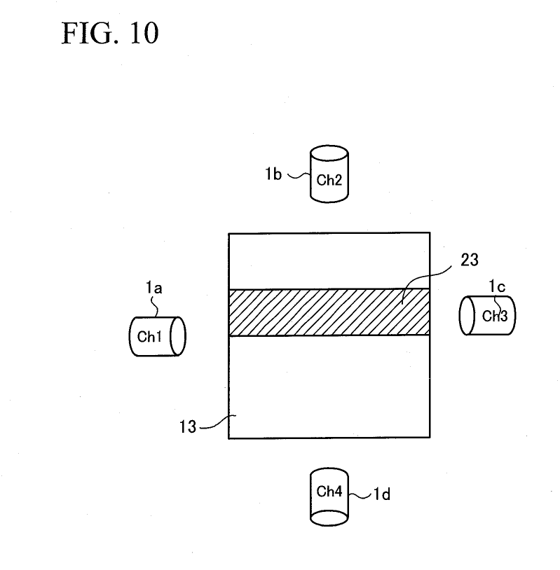

FIG. 10 is a view showing an example of the setting of the reference observation region.

As shown in FIG. 10, the reference observation region 13 has the same size as that of the defect observation region 12. In addition, the reference observation region 13 is positioned in advance such that the position of a reference pattern 23 in the reference observation region 13 coincides with the position of the observation target pattern 22 in the defect observation region 12.

When the observation target pattern 22 in the defect observation region 12 is a simple line pattern, the reference observation region 13 may be set by shifting the defect observation pattern 12 in the extending direction of the observation target pattern 22. Alternatively, when there is the same reference pattern in a different region on the substrate, the reference observation region 13 may be set with reference to the design data.

Although not particularly limited, the electron detectors 1a to 1d herein are disposed in the lateral direction and the longitudinal direction of the rectangular reference observation region 13.

Next, in step S14 of FIG. 7, the electron scanning unit 1 scans the reference observation region 13 with the electron beam. Hence, the signal processing unit 107 generates the second differential image of the reference observation region 13. Here, the signal processing unit 107 obtains the second differential image by finding a difference between the signals from the electron detectors 1b and 1d arranged in the direction orthogonal to the edges of the reference pattern 23.

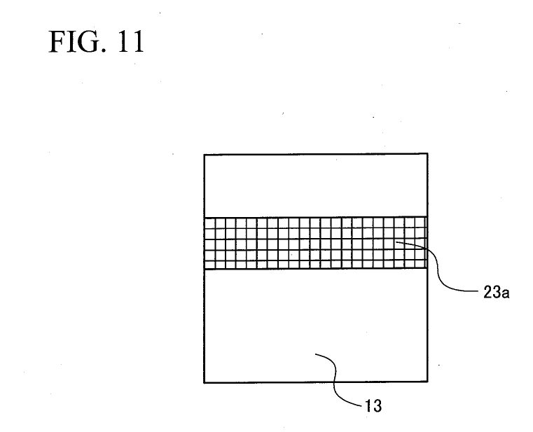

FIG. 11 is a view showing a pattern which appears in the second differential image.

The second differential image is obtained by finding a difference between the signals Ch2 and Ch4 from the electron detectors 1b and 1d which are arranged in the direction orthogonal to the edges of the reference pattern 23. In the differential signals, the edges of the reference pattern 23 are emphasized. For this reason, as shown in FIG. 11, an irregularity pattern 23a reflecting irregularities in the reference pattern 23 appears in the second differential image.

Next, in step S15 (see FIG. 7), the analysis unit 103 of the pattern inspection apparatus 100 (see FIG. 1) obtains the three-dimensional shape of the defect observation region 12 by subjecting the first differential image to integral process. The integral process is performed in accordance with the following method.

First, a plurality of differential profiles in the direction used for finding the difference (the lateral direction in the case of FIG. 9) are extracted from the first differential image (see FIG. 9) at a predetermined pitch in the longitudinal direction. Then, integral of the differential profiles are determined in the lateral direction of the differential profiles to obtain integral profiles representing distribution of the integrated values. The integral profiles reflect a three-dimensional shape of the pattern which emerges in the differential image.

As described above, in the embodiment, when the three-dimensional shape data of the defect is acquired from the first differential image, the integral profiles are obtained in terms of the direction different from the scanning direction of the electron beam which causes the luminance unevenness. Thus, the embodiment makes it possible to suppress an error in a height direction attributed to the luminance unevenness.

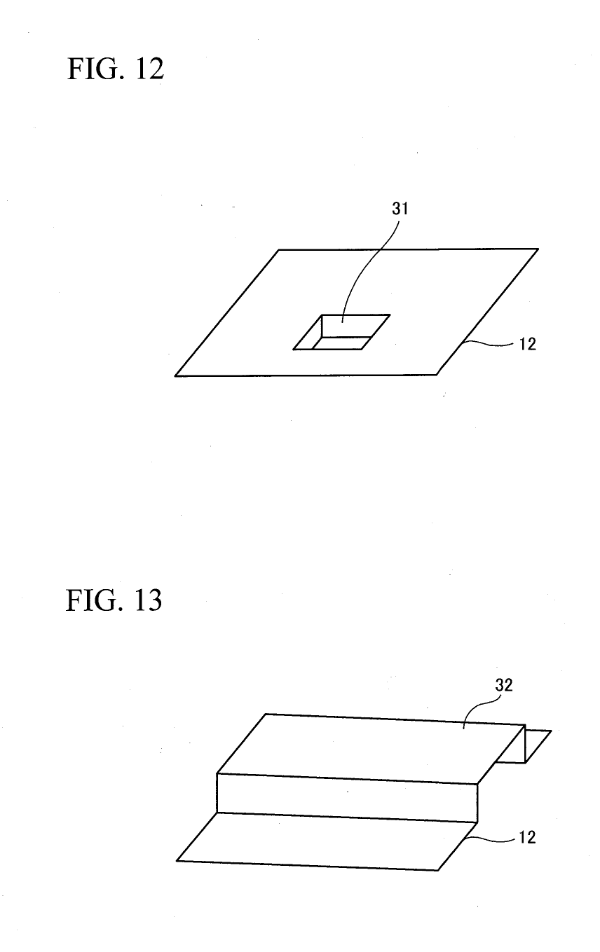

FIG. 12 is a view showing the three-dimensionally arranged integral profiles of the first differential image of FIG. 9. As shown in FIG. 12, the three-dimensional shape of the defect 21a (see FIG. 9) observed in the first differential image emerges here as a pattern 31. It is to be noted that the observation target pattern 22 and the luminance unevenness are eliminated in the course of obtaining the differential profiles, and are therefore not reflected in the integral profiles.

Thus, only the three-dimensional shape of the defect 21 is extracted from the defect observation region 12.

Next, in step S16 (see FIG. 7), the analysis unit 103 obtains the three-dimensional shape of the reference observation region 13 by subjecting the second differential image to integral process. The integral process is performed in accordance with the following method.

First, a plurality of differential profiles in the direction used for finding the difference (the longitudinal direction in the case of FIG. 11) are extracted from the second differential image (see FIG. 11) at a predetermined pitch in the lateral direction. Then, integral of the differential profiles are determined in the longitudinal direction of the differential profiles to obtain integral profiles representing distribution of the integrated values. The integral profiles reflect a three-dimensional shape of the reference pattern 23a.

FIG. 13 is a view showing the three-dimensionally arranged integral profiles of the second differential image of FIG. 11. As shown in FIG. 13, the three-dimensional shape of the reference pattern 23a observed in the second differential image appears here as a pattern 32.

Thus, the three-dimensional shape of the observation target pattern 22 in the case of not including the defect 21 is reproduced as the pattern 32.

Next, in step S17, the analysis unit 103 generates another three-dimensional shape data by adding the three-dimensional shape data obtained from the second differential image to the three-dimensional shape data obtained from the first differential image.

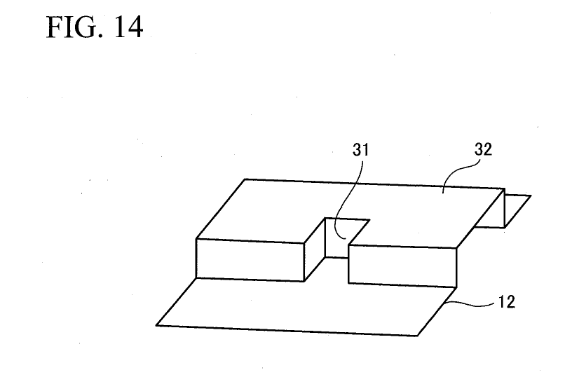

FIG. 14 is a view showing the three-dimensional shape data obtained by combining the three-dimensional shape data of FIG. 12 and the three-dimensional shape data of FIG. 13 together.

The three-dimensional shape of the observation target pattern 22 including the defect 21 in the defect observation region 12 is reproduced by combining the three-dimensional shape data of FIG. 12, which extracts only the defect 21, with the three-dimensional shape data of FIG. 13, which represents the pattern 23 without defects.

As described above, in the embodiment, the three-dimensional shape of the observation target pattern 22 is generated from the defect 21 and the reference pattern 22, so that it is possible to eliminate recesses and projections to be generated due to the luminance unevenness appearing on the SEM images. Thus, the accurate three-dimensional shape of the observation target pattern 22 may be reproduced.

In addition, since the recesses and the projections attributed to the luminance unevenness are eliminated, it is possible to measure the height of a pattern and the depth of the defect more accurately.

### EXAMPLE

A description will be given below of an example of a pattern inspection on a pattern and a defect formed on a photomask substrate, which is conducted by using the pattern inspection apparatus 100.

This example uses a sample prepared by forming a chromium film with a thickness of about 60 nm on a substrate made of fused silica, and then forming a line pattern by patterning the chromium film.

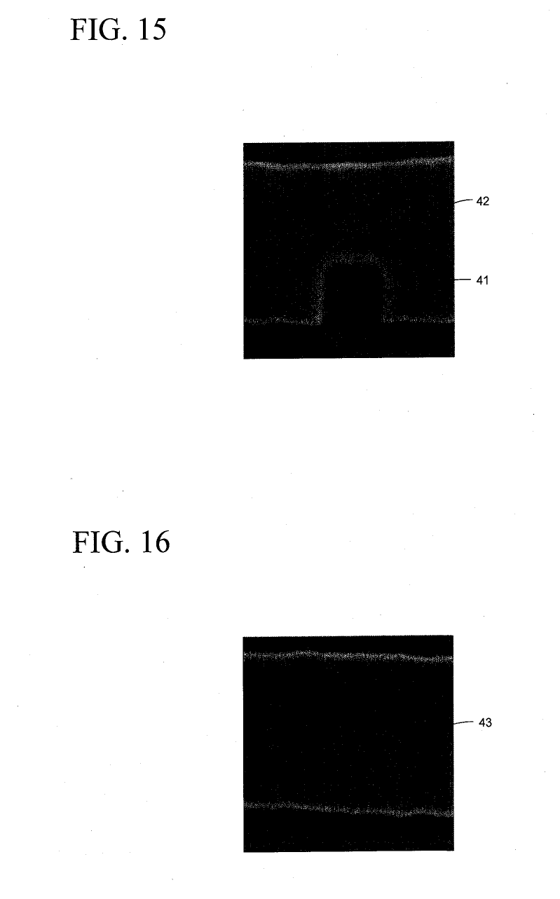

FIG. 15 is a SEM image of the line pattern on the sample of the example. The SEM image of FIG. 15 is captured while the electron beam scans in the longitudinal direction of FIG. 15.

As shown in FIG. 15, the line pattern 42 extends in the lateral direction in the defect observation region, and the defect 41 exists on the line pattern 42. The defect 41 is a scratch defect which a part of the line pattern 42 is scratched off. Luminance unevenness is observed on two sides of the defect 41 in the scanning direction of the electron beam.

Next, the reference observation region is set on the same line pattern 42 at a different place, and a SEM image of the reference observation region is captured while causing the electron beam to scan the reference observation region. In the following, a reference pattern in the reference observation region corresponding to the line pattern 42 will be referred to as a line pattern 43.

FIG. 16 is a SEM image of the reference observation region of the example. The line pattern 43 having the same line width as that of the line pattern 42 appears in the reference observation region. The line pattern 43 in the reference observation region does not include any defects or luminance unevenness attributed to such defects.

Next, the first differential image of the defect observation region of FIG. 15 is obtained by finding the difference between the signals Ch1 and Ch3 from the electron detectors 1a and 1c which are arranged in the direction parallel to the line pattern 42.

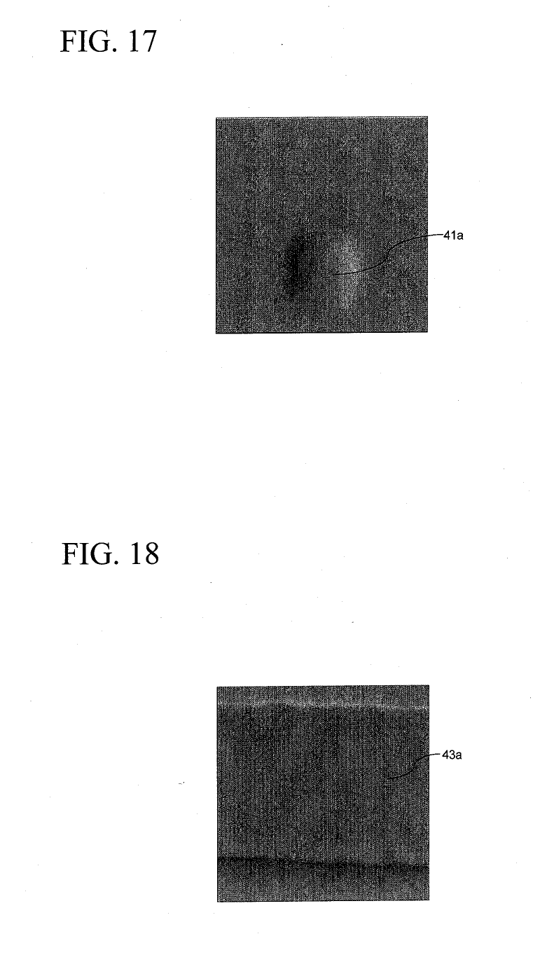

FIG. 17 is a view showing the first differential image of the defect observation region of FIG. 15.

In the first differential image, the difference in the direction parallel to the line pattern 42 is found. Accordingly, the edges of the line pattern 42 are eliminated from the image and only the defect 41 is left therein.

Next, the second differential image of the reference observation region of FIG. 16 is obtained by finding the difference between the signals Ch2 and Ch4 from the electron detectors 1b and 1d which are arranged in the direction perpendicular to the line pattern 43.

FIG. 18 is a view showing the second differential image of the reference observation region of FIG. 16.

In the second differential image, the difference in the direction orthogonal to edges of the line pattern 43 is found. Accordingly, the edges of the line pattern 43 are displayed each with the luminance corresponding to the inclinations of the edges.

Next, the three-dimensional shape of the defect 41 is obtained by finding the distribution of the differential values (the differential profiles) in the lateral direction in terms of the first differential image of FIG. 17, and further subjecting the differential profiles to the integral process in the lateral direction.

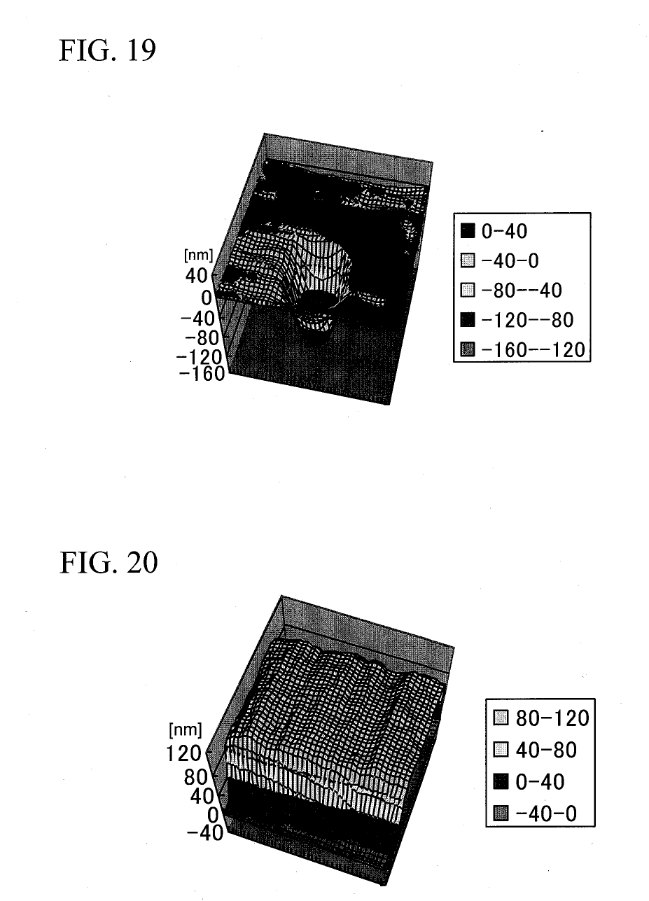

FIG. 19 is a graph showing the three-dimensional shape obtained by subjecting the first differential image to the integral process.

Likewise, the three-dimensional shape of the pattern 43 is obtained by finding the distribution of the differential values (the differential profiles) in the longitudinal direction in terms of the second differential image of FIG. 18, and further subjecting the differential profiles to the integral process in the longitudinal direction.

FIG. 20 is a graph showing the three-dimensional shape obtained by subjecting the second differential image to the integral process.

Next, the three-dimensional shape of the defect observation region is obtained by combining three-dimensional shape data of FIG. 19 and three-dimensional shape data of FIG. 20 together.

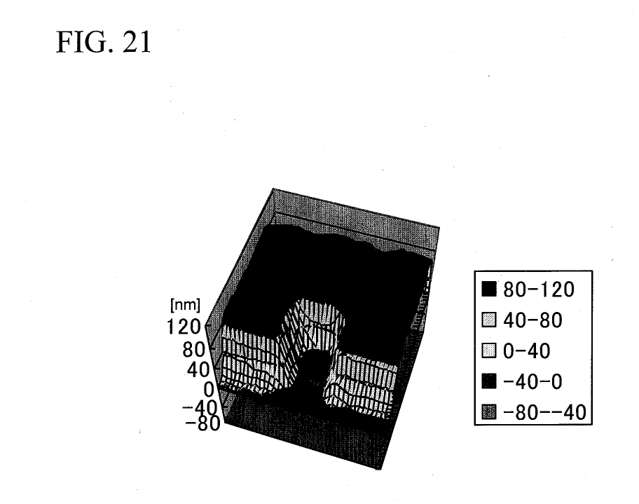

FIG. 21 is a graph showing the three-dimensional shape obtained by combining the three-dimensional shape data of FIG. 19 and the three-dimensional shape data of FIG. 20 together.

As shown in FIG. 21, it is confirmed that the three-dimensional shape thus obtained may prevent the recesses and projections being produced, which might have been caused by the luminance unevenness attributed to the defect.

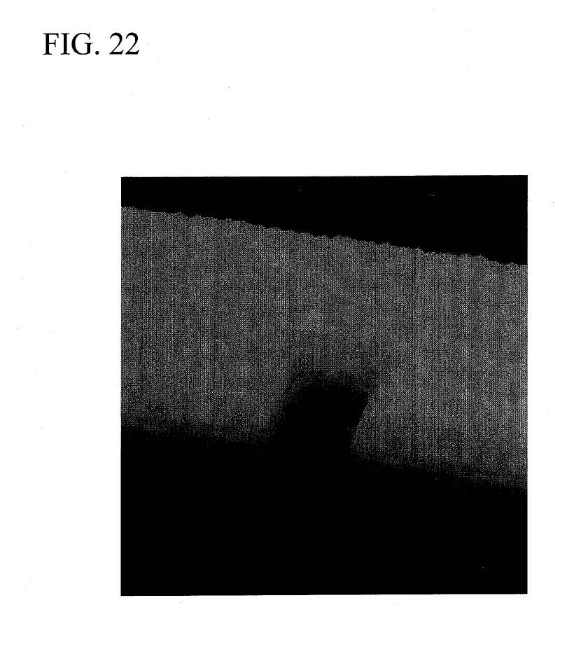

FIG. 22 is a view showing a result of observation of the defect observation region of FIG. 15 by means of the atomic force microscopy (AFM).

The result of the measurement by the AFM shown in FIG. 22 conforms to the three-dimensional shape of FIG. 21.

This fact confirms that the example successfully obtains the three-dimensional shape of the defect observation region.

The above descriptions have been given of the example in which each of the electron detectors 1a to 1d is disposed in the direction orthogonal to the corresponding side of the rectangular observation region. However, the present invention is not limited only to this configuration.

For example, as described in Patent Document 2, the electron detectors 1a to 1d may be disposed in diagonal directions of the rectangular observation region. In this case, the above-described embodiment may be realized by artificially generating SEM images in the directions orthogonal to the sides of the observation region by adding up signals of the adjacent electron detectors.

What is claimed is:

1. A pattern inspection method using a scanning electron microscope provided with a plurality of electron detectors disposed around an optical axis of a primary electron beam, the method comprising the steps of:
setting a defect observation region including an observation target pattern having a defect;
acquiring scanning electron microscopic images respectively with the plurality of electron detectors by scanning the defect observation region with the primary electron beam;
acquiring a first differential image by finding a difference between the scanning electron microscopic images acquired with the electron detectors disposed in the same direction as an extending direction of an edge of the observation target pattern;
setting a reference observation region including a reference pattern having the same shape as the observation target pattern;
acquiring scanning electron microscopic images respectively with the plurality of electron detectors by scanning the reference observation region with the primary electron beam;
acquiring a second differential image by finding a difference between the scanning electron microscopic images acquired with the electron detectors disposed in a direction orthogonal to an extending direction of an edge of the reference pattern; and
reproducing a three-dimensional shape of the observation target pattern based on the first differential image and the second differential image.

2. The pattern inspection method according to claim 1, wherein the step of reproducing a three-dimensional shape comprises the steps of:
generating a three-dimensional shape of the defect by subjecting the first differential image to integral process in the extending direction of the edge of the observation target pattern;
generating a three-dimensional shape of the reference pattern by subjecting the second differential image to integral process in the direction orthogonal to the extending direction of the edge of the reference pattern; and
adding up a result of the integral process for the first differential image and a result of the integral process for the second differential image.

3. The pattern inspection method according to claim 1, wherein
the defect observation region is set at a portion where defect position coordinate data indicating a position of the defect determines that the defect is present, and
the reference observation region is set at a portion where the defect position coordinate data determines that the defect is absent.

4. A pattern inspection apparatus comprising:
an observation region setting unit configured to set a defect observation region on a surface of a sample at a portion where an observation target pattern having a defect is present, and to set a reference observation region on the surface of the sample at a portion having a reference pattern of the same shape as the observation target pattern and having no defect;
an electron scanning unit configured to scan the defect observation region and the reference observation region with a primary electron beam;
a plurality of electron detectors disposed around an optical axis of the primary electron beam and each configured to detect electrons emitted from the surface of the sample by irradiation of the primary electron beam;
a signal processing unit configured to generate a plurality of scanning electron microscopic images respectively based on detection signals from the plurality of electron detectors; and
an analysis unit configured to calculate a three-dimensional shape of the observation target pattern based on the plurality of scanning electron microscopic images, wherein
the analysis unit reproduces the three-dimensional shape of the observation target pattern by executing the steps of:
generating a three-dimensional shape of the defect based on a first differential image of the defect observation region acquired by finding a difference between the scanning electron microscopic images acquired with the electron detectors disposed in the same direction as an extending direction of an edge of the observation target pattern;
generating a three-dimensional shape of the reference pattern based on a second differential image of the reference observation region acquired by finding a difference between the scanning electron microscopic images acquired with the electron detectors disposed in a direction orthogonal to an extending direction of an edge of the reference pattern; and
combining the three-dimensional shape of the defect and the three-dimensional shape of the reference pattern together.

5. The pattern inspection apparatus according to claim 4, wherein
the analysis unit generates the three-dimensional shape of the defect by subjecting the first differential image to integral process in the extending direction of the edge of the observation target pattern, and
the analysis unit generates the three-dimensional shape of the reference pattern by subjecting the second differential image to integral process in the direction orthogonal to the extending direction of the edge of the reference pattern.

6. The pattern inspection apparatus according to claim 5, wherein the analysis unit reproduces the three-dimensional shape of the observation target pattern by adding up a result of the integral process for the first differential image and a result of the integral process for the second differential image.

7. The pattern inspection apparatus according to claim 4, wherein
the observation region setting unit refers to defect position coordinate data indicating a position of the defect,
the observation region setting unit sets the defect observation region at a portion where the defect is determined to be present, and
the observation region setting unit sets the reference observation region at a portion where the defect is determined to be absent.
